(19) United States
(12) Patent Application Publication
(10) Pub. No.: US 2007/0004237 A1
(43) Pub. Date: Jan. 4, 2007

(54) Printed circuit board

(75) Inventor: Ju-Sheng Chen, Hsinchu City (TW)

Correspondence Address: BRUCE H. TROXELL;SUITE 1404, 5205 LEESBURG PIKE, FALLS CHURCH, VA, 22041, US

(73) Assignee: LITE-ON IT CORPORATION

(21) Appl. No.: 11/315,370

(22) Filed: Dec. 23, 2005

(30) Foreign Application Priority Data
Jul. 1, 2005 (TW) 94122374

(51) Int. Cl. H05K 1/00

(52) U.S. Cl. 439/55

(57) ABSTRACT

A printed circuit board includes a substrate and a circuit layer located on top of the substrate. The circuit layer further includes a plurality of lattice holes. By providing the lattice holes on the circuit layer, occurrence of bubbles between the circuit layer and the substrate after a high-temperature process can be substantially avoided

### BACKGROUND OF THE INVENTION

(1) Field of the Invention

The invention relates to a printed circuit board (PCB), and more particularly to a PCB that can endure a high-temperature manufacturing process.

(2) Description of the Prior Art

Due to the lack of environmental protection consciousness in the past, conventional methods for implanting various devices onto a PCB, such as the dual in-line package (DIP) and the surface mount technology (SMT), usually utilize toxic tin-lead solders directly to ensure the electrical and solid connection between the devices and the circuit on the PCB.

Typically, a conventional tin-lead solder is composed of 63% tin and 37% lead by weight. Its melting point is about 183° C. On the other hand, a typical soldering process usually has an operation temperature up to 210° C.

In recent years as the awareness of the environmental protection, a growing number of international organizations have enforced specific regulations to prohibit the use of toxic lead in the solder, for example European WEEE Waste Electrical and Electronic Equipment regulations. To conform to requirements of those regulations, the use of lead-free solders has gradually been developing.

At present, common lead-free solders are simple an alloy of tin, silver, and copper and have a melting point up to 217° C., which is much higher than that of conventional tin-lead solders. Therefore, the operation temperature for such kind of solders is raised to 250° C. or higher.

Because of the obvious increase in the operation temperature of the lead-free soldering process, the conventional manufacturing processes involving the soldering definitely require new standards. The following will illustrate the structures of printed circuit boards and the problems occurred in the lead-free manufacturing process.

The circuit structure on the surface of the printed circuit board includes a circuit area and a ground area. The circuit area forms the circuits for conveying electrical signals to the implanted electronic devices, while the ground area is used for grounding.

FIG. 1 includes a top view and a lateral cross-sectional view of a conventional printed circuit board 2. The printed circuit board 2 includes a substrate 6 and a circuit layer 8 on top of the substrate 6. The substrate 6 can be categorized as an FR1 substrate, a CEM1 substrate, or a CEM3 substrate, based on its material. The circuit layer 8, usually made of copper, is etched to form the circuit area and the ground area as described above. In addition, the circuit layer 8 is painted with an anti-flux layer 10 to protect the circuit structure on the printed circuit board 2.

Empirically, while using lead-free solders to process a lead-free manufacture, bubbles 4 usually occur vastly on the ground area of the circuit layer 8. That is to say that the circuit structure in the bubbled area 4 would be separated from the PCB 6 and, as a result, the operation of the bubbled circuit structure would be unpredictable.

Currently, two reasons causing the aforesaid bubbling phenomenon have been found. One is because the thermal expansion coefficients of the circuit layer 8 and the substrate 6 are distinct, and the degree of the thermal expansion in between would become larger different as the working temperature in the manufacturing process increases. A thermal stress resulted from the difference of thermal expansion leads to the detachment between the circuit layer 8 and the substrate 6 after a heating process. Another reason is because, as the increase of the processing temperature, the substrate 6 will vapor and generate steam. Some of the steam will reside between the circuit layer 8 and the substrate 6 after the process and finally lead to the formation of the bubbles 4.

To resolve the above problems and to provide one kind of printed circuit board that can endure high-temperature manufacturing process are clear topics to the researchers in the PCB industry.

### SUMMARY OF THE INVENTION

The primary object of the present invention is to provide one kind of printed circuit boards which can endure a high-temperature environment so as effectively to avoid the defect that blows up the circuit layer after a lead-free manufacturing process.

According to the present invention, the printed circuit board comprises one substrate and at least one circuit layer on the substrate, in which the circuit layer further includes a plurality of holes arranged into at least a lattice pattern.

By providing the holes in lattice patterns to the circuit layer of the printed circuit board in accordance with the present invention, generation of bubbles in the circuit layer after a high-temperature manufacturing process would be effectively prevented. As a result, the electrical quality of the printed circuit board as well as the devices can be ensured.

The merit and concept of the present invention can be further understood by the following detailed description of invention and the attached drawings.

### BRIEF DESCRIPTION OF THE DRAWINGS

FIG. 1 includes a top view of a conventional printed circuit board and a schematic cross-sectional view of the printed circuit board along the line in the top view.

FIG. 2 is a schematic top view of a preferred printed circuit board in accordance with the present invention.

FIG. 3 includes a top view of partial part of the preferred printed circuit board in accordance with the present invention and a schematic cross-sectional view of the printed circuit board along the line in the top view.

FIG. 4 shows the specifications for the lattice holes and the lattice area in accordance with the present invention.

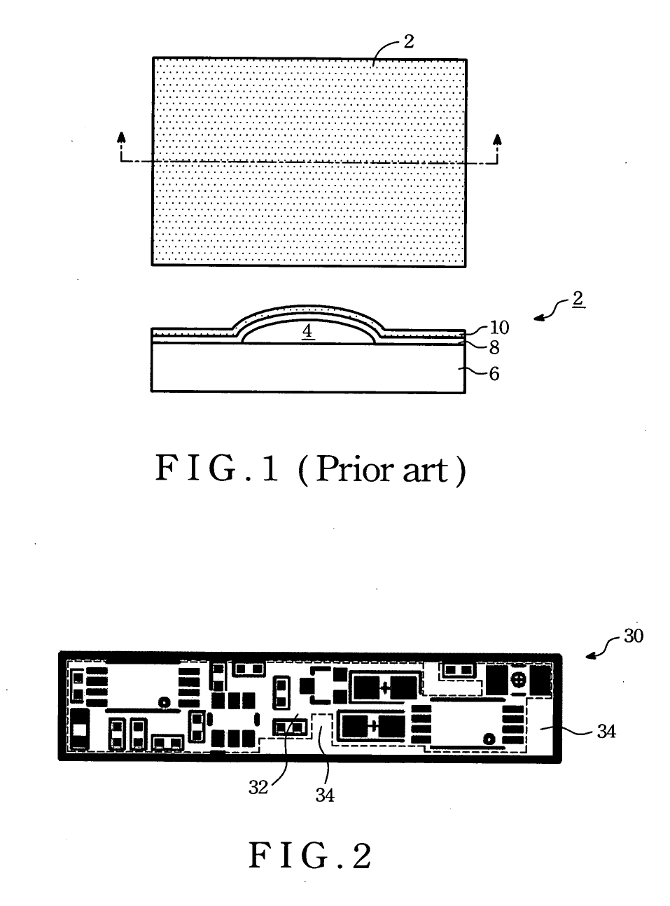

### DESCRIPTION OF THE PREFERRED EMBODIMENT

The invention disclosed herein is directed to a printed circuit board. The original innovation was conceived of avoiding the bubbles being generated under the circuit layer of the printed circuit board as processing the SMT with lead-free solders for manufacturing the motherboard for disc drives.

At present, the printed circuit board of the motherboard for the disc drives comprises a substrate layer and circuit layers on both sides of the substrate. The circuit layer is made of a conductive material such as the copper. In addition, substrates made of the FR1, the CEM1 or the CEM3 are usually employed as the substrate for this type of the printed circuit board.

In one embodiment of the present invention, the copper is used to form the circuit layer so as to demonstrate the related technical characteristics of the present invention.

As shown in FIG. 2, it is a schematic top view of the preferred printed circuit board 30 in accordance with the present invention. The circuit structure on the printed circuit board 30 is formed by etching. In the etching process, the circuit layer is etched into a circuit area 32 and a ground area 34. The circuit area 32 is formed into circuitries for conveying electrical signals to or from electronic devices implanted on the PCB 30. The ground area 34 is for grounding and for protecting the circuitries from electromagnetic interference (EMI).

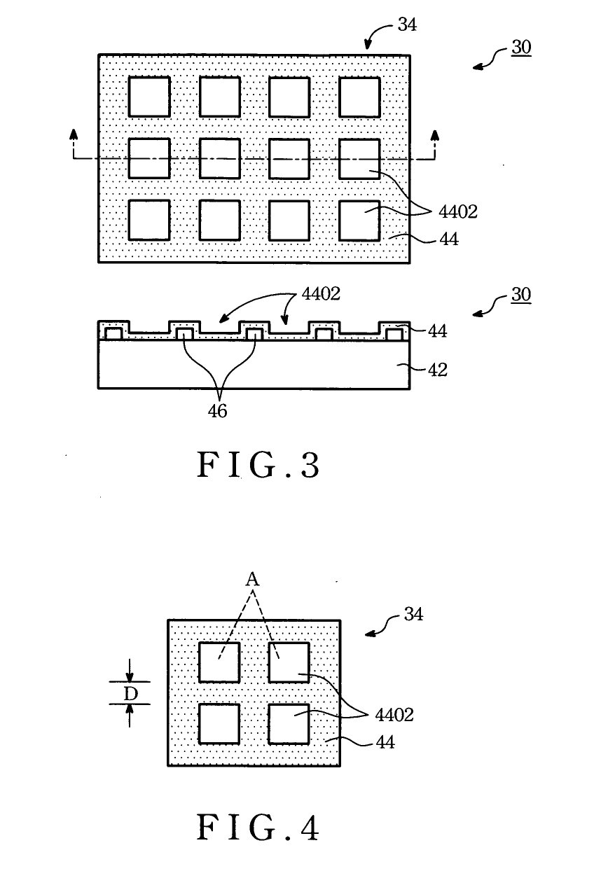

Referring to FIG. 3, a top view of the partial part of the preferred printed circuit board 30 in accordance with the present invention and a schematic cross-sectional view of the printed circuit board 30 along the line in the top view are shown. This printed circuit board 30 comprises one substrate 42, at least one circuit layer 44 (i.e. a copper layer), and at least one anti-flux layer 46. The circuit layer 44 is located on top of the substrate 42 and further includes a plurality of holes 4402 (or say lattice holes) arranged into at least one lattice area. The anti-flux layer 46 is placed on top of the circuit layer 44.

In the embodiment of the present invention, the lattice holes 4402 are designated only to the ground area 34 of the circuit layer 44 so as to make the ground area 34 formed as a lattice area. By introducing the lattice holes 4402 to the ground area 34 of the circuit layer 44 (i.e. by eating out some materials in the ground area 34 but without affecting the configuration of the ground area 34), the face-to-face contact area between the substrate 42 and the circuit layer 44, especially at the ground area 34, can be reduced. Also, by introducing the lattice holes 4402 to narrow each shielding area of the concerned ground area 34 with respect to the substrate 42, the thermal stress induced from the difference in the thermal expansion coefficients between the substrate 42 and the circuit layer 44 during the high temperature manufacturing process can be substantially reduced. The decrease of the thermal stress will prevent from the detachment between the circuit layer 44 and the substrate 42 after a high-temperature process. In addition, in the process, the steam produced in the substrate 42 can be released into the atmosphere via the lattice holes 4402, so that the steam would not easily accumulate under the circuit layer 44.

Referring to FIG. 4 for further illustration, FIG. 4 is a schematic top view including the lattice area 34 and the lattice holes 4402 on the circuit layer 44 of the present invention. Each area A, symbolizing the area of the lattice holes 4402, is ranged between 0.01 mm² and 0.2 mm², and the distance D between any two adjacent lattice holes 4402 is ranged between 0.01 mm and 0.5 mm. The arrangement of those lattice holes 4402 can be an array pattern or a scattered pattern. Also, the lattice holes 4402 can be of any geometric shape, such as a circle or a polygon and so on.

In accordance with the printed circuit board of the present invention, by employing the design of the circuit layer with lattice-hole area to the printed circuit board, the effect of the thermal expansion due to the high temperature manufacturing process can be substantially reduced, so that the capability of substrate to sustain the high temperature can be improved. Therefore, the bubble-like defects generated between the circuit layer and the substrate can be avoided and thus the reliability of the PCB products can be increased. In addition, by providing the circuit layer with lattice holes, the endurance of the substrate against high temperatures can be increased. Therefore, conventional materials for the substrates can be still used in applying the PCB of the present invention.

According to the detailed description of the embodiment of the present invention, the characteristics and concepts of the present invention are expected to be illustrated more clearly, rather than to limit the range of the present invention in accordance with the preferred embodiment disclosed as above. To the contrary, the object is expected to cover every variety and isometric arrangement in the scope of patent applied by the present invention.

I claim:

1. A printed circuit board, comprising:
a substrate; and
at least one circuit layer, located on top of the substrate, further including a plurality of lattice holes thereof arranged into at least one lattice area.

2. The printed circuit board according to claim 1, further including an anti-flux layer located on top of said circuit layer.

3. The printed circuit board according to claim 1, wherein said circuit layer is made of a conductive material.

4. The printed circuit board according to claim 1, wherein said circuit layer is made of a copper.

5. The printed circuit board according to claim 1, wherein said lattice hole has an area ranged between 0.01 mm² and 0.2 mm².

6. The printed circuit board according to claim 1, wherein a distance between any two adjacent lattice holes is ranged between 0.01 mm and 0.5 mm.

7. The printed circuit board according to claim 1, wherein said printed circuit board is a printed circuit board used in a disc drive.

8. The printed circuit board according to claim 1, wherein said circuit layer further includes a circuit area and a ground area, said lattice holes being located in said ground area.

9. The printed circuit board according to claim 1, wherein each of said lattice holes has a shape of polygon.

10. The printed circuit board according to claim 1, wherein each of said lattice holes has a circular shape.
